(19) United States
(12) Patent Application Publication
(10) Pub. No.: US 2005/0062164 A1
(43) Pub. Date: Mar. 24, 2005

(54) Method for improving time dependent dielectric breakdown lifetimes

(75) Inventors: Keng-Chu Lin, Ping-Tung (TW); Tien-I Bao, Hsin-Chu (TW); Syun-Ming Jang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/668,702

(22) Filed: Sep. 23, 2003

(51) Int. Cl. H01L 29/00

(52) U.S. Cl. 257/759

(57) ABSTRACT

The present disclosure provides a method for increasing a time dependent dielectric breakdown lifetime of a semiconductor device and a structure fabricated using this method. The method includes depositing a first layer and then forming a glue layer on the first layer. A treatment process, which may use a plasma or an electron beam, is performed on the glue layer. The treatment process improves an interface between the glue layer and the first layer. The treatment process may also affect electrical properties of the glue layer. A second layer may then be deposited onto the treated glue layer.

### BACKGROUND

The present disclosure relates generally to the field of semiconductor processing, and more particularly, to a method for improving device performance and reliability for submicron integrated circuit technologies.

An integrated circuit (IC) is formed by creating one or more devices (e.g., circuit components) on a substrate using a fabrication process. As the geometry of such devices is reduced to the submicron level, the IC's active device density (i.e., the number of devices per IC area) and functional density (i.e., the number of interconnected devices per IC area) has become limited by the fabrication process. An IC fabrication process generally has a number of limitations that affect the formation of a device. One of these limitations relates to metallization, which involves the growth, formation, and/or deposition of a conducting material.

Reduced geometry devices are generally developed using metallization processes that are governed by standards for metal film quality and electrical reliability. The standards are used because defects and particles generated by a metallization process may reduce device electrical yield and reliability. If not removed, these defects may even cause a short between metal lines.

One problem associated with metallization in reduced geometry devices is a reduced time dependent dielectric breakdown (TDDB) lifetime. The TDDB lifetime is the time in which an oxide or inter metal dielectric (IMD) breaks down through stress caused by a high electric field. The TDDB lifetime is generally an indicator of metal interconnect electromigration and of a metal barrier or dielectric's ability to prevent metal diffusion. As device geometries shrink, the TDDB lifetime of the IMD may be reduced, particularly at interfaces between the IMD and metal lines. High electrical stress, especially in reduced geometry devices with geometries of 0.1 micron or less, may result in IMD failure.

Metallization of integrated circuits may be accomplished using a damascene process, in which a substrate is inlaid with metal. Damascene and a related process, known as dual damascene (both referred to henceforth as “damascene”), have become widely used in IC manufacturing for devices with geometries of 0.1 micron or less. Generally, the damascene process involves creating interconnect schemes by cutting trenches into a dielectric and then filling those trenches with metal. Any excess metal is polished away.

Damascene processes often use copper as a bulk filling interconnect metal because of its low resistance. However, copper suffers from high diffusivity when used with many common insulating materials, such as silicon oxide and oxygen containing polymers. For example, copper deposited on an oxide may form copper oxide at or near 200° C. Similarly, copper tends to diffuse during high temperature processing with a polyimide, causing severe corrosion of the copper and the polyimide. The corrosion may result in loss of adhesion, delamination, voids, and total failure of the device. Therefore, barrier layers may be incorporated into the damascene process using refractory metals as cladding around the copper. Materials such as TiN, TaN, TiW, or other nitride containing refractory metals may be employed, as may other materials that prevent copper diffusion, promote adhesion, and possess appropriate electrical properties.

Other materials used in fabrication processes may contribute to device quality. A semiconductor device may be comprised of various layers, including IMD films, metal layers, and antireflective coating (ARC) layers. The composition of underlying layers may be altered by the properties of subsequent layers and the processes used to create the subsequent layers, leading in some cases to catastrophic IMD failures.

These layers may suffer internal stress due to lattice mismatches at film interfaces. This stress may be enhanced by changes in the environment, the application of force, thermal cycling, and other stress inducing processes. Furthermore, low dielectric constant (low-k) films may exhibit high porosity and low density, which can yield a film with low hardness and high susceptibility to stress. Low-k films are sensitive to stresses that may occur during the deposition of the low-k film, the deposition of earlier film layers, the deposition of subsequent layers, and thermal cycling that occurs during the fabrication process. These low-k dielectric film stresses can cause film cracking and peeling. The stresses associated with chemical mechanical polishing (CMP) can cause similar problems, and the induced mechanical force that occurs with CMP may also cause metal such as copper to be incorporated into the low-k dielectric. Process technologies for low-k dielectric films often rely on post treatment processes such as thermal annealing and plasma treatment to increase the film hardness and to help reduce moisture uptake of the low-k dielectric.

Etch stop layers, which may be used in conjunction with a damascene metallization process, also affect to device quality. An etch stop layer helps to protect an underlying metal layer from oxidation due to moisture and exposure to air. The etch stop layer also provides a process end point for the formation of a via for the next layer of metal interconnect. However, the interaction of the etch stop layer, the low-k dielectric layer, and the copper and barrier layers can be a source of reliability problems in the metallization process.

Furthermore, line-to-line leakage may result from the breakdown of an IMD, and is a concern in copper damascene interconnects. The line-to-line leakage problem continues to plague manufacturers of reduced geometry devices as they seek new methods of improving the IMD TDDB lifetime. The quality of the interface between a low-k IMD and a subsequent etch stop layer plays a role in determining the IMD TDDB lifetime.

Accordingly, a method is needed to improve the TDDB lifetimes of semiconductor devices, including MD interfaces in damascene structures.

### SUMMARY

In one embodiment, a method is provided for increasing a time dependent dielectric breakdown lifetime of a semiconductor device that has a first layer underlying a second layer. The method comprises forming a glue layer on the first layer, performing an inter-treatment on the glue layer, wherein the inter-treatment improves an interface between the glue layer and the first layer; and depositing the second layer onto the inter-treated glue layer.

In another embodiment, a method for increasing a dielectric breakdown lifetime of a semiconductor device is provided. The method comprises depositing a dielectric layer and depositing a glue layer on the dielectric layer. Either a plasma treatment process or an electron beam treatment process is selected and applied to the glue layer. The treatment process enhances an adhesiveness of the glue layer and the dielectric layer.

In still another embodiment, a damascene structure having an increased time dependent dielectric breakdown lifetime is provided. The structure comprises a first layer that is at least partially formed from a dielectric material. A treated glue layer adheres to the first layer, where the adhesiveness of the glue layer is due in part to a treatment performed on the glue layer prior to the deposition of any layer above the glue layer. A second layer is formed on the glue layer.

### BRIEF DESCRIPTION OF THE DRAWINGS

FIG. 1 is a flowchart of a method for fabricating a damascene structure having an improved time dependent dielectric breakdown lifetime.

FIGS. 2-4 are cross-sectional views of the damascene structure fabricated using the method of FIG. 1.

FIG. 5 is a graph of line-to-line leakage current versus electrical stress comparing structures fabricated with and without using the method of FIG. 1.

FIG. 6 is a graph of a Weibull distribution profile of time dependent dielectric breakdown lifetimes for dielectric layers fabricated without using the method of FIG. 1.

FIG. 7 is a graph of a Weibull distribution of time dependent dielectric breakdown lifetimes for dielectric layers fabricated using the method of FIG. 1.

### DETAILED DESCRIPTION

The present disclosure relates generally to the field of semiconductor processing, and more particularly, to a method for improving device performance and reliability for submicron integrated circuit technologies. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

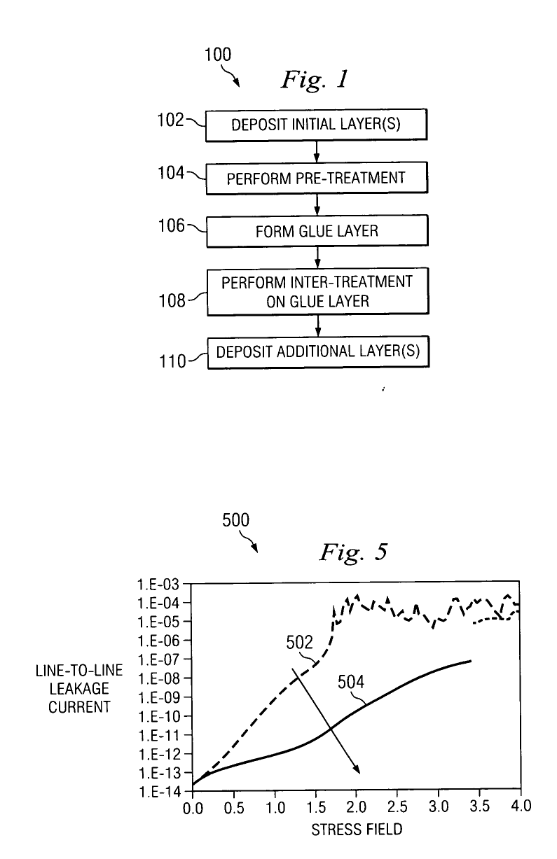

Referring to FIG. 1, a damascene metallization process 100 may be used to enhance IMD reliability and stability by increasing the time dependent dielectric breakdown (TDDB) lifetime of a semiconductor device. In the present example, the process 100 may be a single or dual copper damascene metallization process. As will be described later in greater detail, the method 100 may be performed on a substrate to form a damascene structure.

In step 102, a series of interconnect structures and layers are deposited onto a substrate. The interconnect structures, which may include interconnect lines, contacts, and/or vias, may provide electrical contact to a semiconductor device or may electrically connect vias and interconnect lines to other interconnect structures. The interconnect structures may be coupled to a series of oxide or inter metal dielectric (IMD) layers, etch stopping layers, capping layers, anti-reflection layers, and/or other suitable material layers that can be utilized in a damascene metallization process.

In step 104, a pre-treatment, such as a plasma treatment, is performed on exposed surfaces of the interconnect structures and an adjacent IMD layer to prevent oxidation of the interconnect structures. The oxidation may increase contact resistance and interfere with the adhesion of subsequent layers. In step 106, a glue layer may be applied to the exposed surfaces of the interconnect structures and the IMD layer. The glue layer provides adhesion and protection to the interconnect structures, and may also serve as an etch stop layer in the creation of subsequent layers.

In step 108, an inter-treatment is performed on the glue layer. The inter-treatment improves the interface quality between the glue layer and the underlying interconnect structures and IMD layer, such that the TDDB can be significantly improved. The inter-treatment can, in some examples, reduce the line-to-line leakage by driving contaminants out of the interface and changing the crystalline structure. The degree to which the inter-treatment improves the glue layer may depend upon the thickness of the glue layer. For example, applying the inter-treatment to a relatively thin glue layer may yield better electrical properties than the same inter-treatment applied to a relatively thick glue layer. Furthermore, the density of the glue layer may also determine the extent to which the inter-treatment improves the electrical properties of the glue layer. In step 110, subsequent layers may be formed on the pre-treated glue layer.

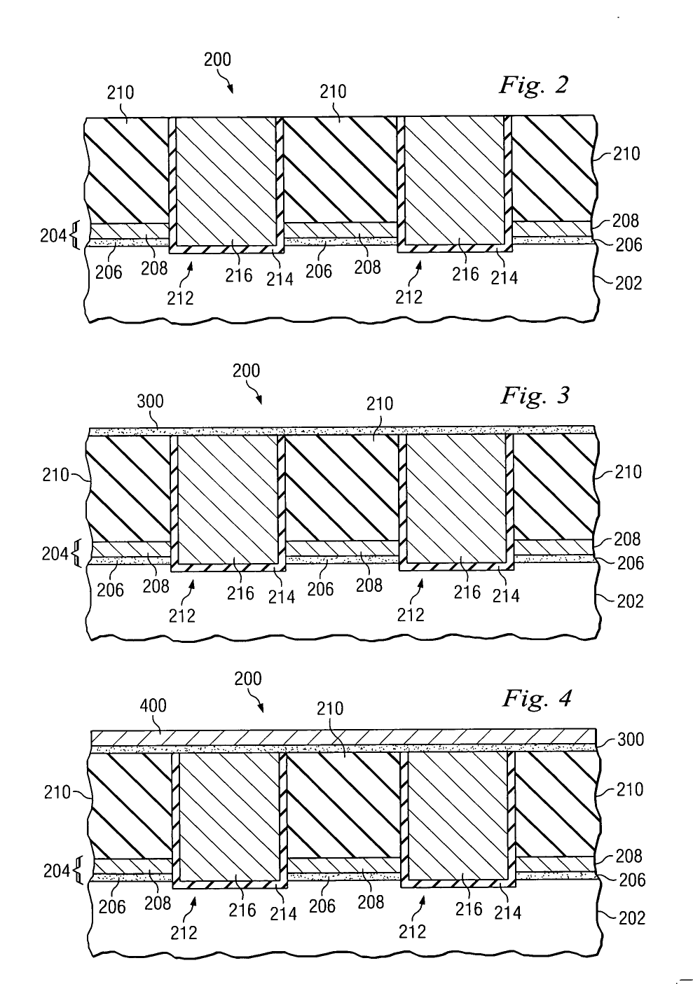

Referring now to FIG. 2 and with continued reference to FIG. 1, a semiconductor structure 200 may be fabricated using the damascene metallization process 100 as follows. A phosphosilicate glass (PSG) layer 202 is covered by one or more etch stop layers 204. In the present example, the etch stop layers 204 include a first glue layer 206 and a first metal layer 208. The first metal layer 208 may be formed of copper, for example, and may further include a copper barrier layer (not shown in detail). An IMD layer 210 may then be deposited onto the etch stop layers 204. The IMD layer 210 may comprise a material such as an extreme low-k (ELK) film. For example, the ELK film may be a porous SiO₂ film where the pores are filled with an inert gas or air to provide the low-k dielectric properties.

A via 212 may be formed through the IMD layer 208 and, if desired, through the etch stop layers 204 and into the PSG layer 202. In the present example, the via 212 is then filled with a barrier film 214 and a copper plug 216. The barrier film 214 may be comprised of TiN, TaN, TiW, and/or other nitride containing refractory metals. The pre-treatment described in step 104 of FIG. 1 may then be performed on the filled via 212 and the adjacent IMD layer 208.

As is known, attempts to improve interface quality using some treatment methods can introduce additional problems. For example, applying a plasma treatment directly to a copper interconnect and IMD layer can cause damage to the copper layer. Similarly, applying a plasma treatment to a copper interconnect and IMD after chemical mechanical polishing (CMP) can damage the copper layer.

Accordingly, referring now to FIG. 3 and with continued reference to FIG. 1, the via 212 and the adjacent IMD layer 210 are then covered with a second glue layer 300, as described in step 106 of FIG. 1. The glue layer 300 may be comprised of SiN, silicon oxide, SiCH, SiCN, SiCO, BLOK (a barrier film from Applied Materials Corp.), or any other appropriate material which can provide adhesion and protection to the interconnect structures. The glue layer 300 may also serve as an etch stop layer in the creation of subsequent layers. The glue layer may be formed by chemical vapor deposition (CVD), plasma enhanced chemical vapor deposition (PECVD), atomic layer deposition (ALD), physical vapor deposition (PVD), evaporation, or any other method known in the art.

After the second glue layer 300 is deposited, the inter-treatment of step 108 of FIG. 1 may be performed. A light hydrogen based plasma treatment may be used, where the reacting gas may be NH₃, H₂ or any other hydrogen based gas. Additionally and/or alternatively, the inter-treatment can utilize He plasma and/or an electron beam. The inter-treatment improves the interface quality between the glue layer and the underlying interconnect structures and IMD layer, such that the TDDB can be significantly improved. The inter-treatment may also, in some examples, reduce the line-to-line leakage by driving contaminants out of the interface and changing the crystalline structure.

A variety of processing conditions may be used to perform the hydrogen plasma based inter-treatment including, for example, an exposure duration of between 0 and 100 seconds at a temperature between approximately 200° C. to 400° C., where 350° C. may be preferable. The exemplary processing conditions may also include a pressure range of 0.5 to 10 torr, an induced RF power from 50 to 2000 Watts, and a hydrogen gas flow of 100 to 2500 standard cubic centimeters per minute (sccm). The plasma used for the inter-treatment may be produced by any of a variety of methods, including a parallel plate capacitive source, an inductively coupled source, a capacitive triode source, an electron cyclotron (ECR) microwave source, a DC coupled source, or a helicon wave source. If an electron beam inter-treatment is used, the power may range from 1000 eV to 8000 eV, and the dosage to the glue layer may be approximately 50 to 500 μC/cm². If He based plasma is used for the inter-treatment, process conditions may include a pressure of 0.5 to 10 torr, a process time of 1 to 100 seconds, and a temperature of approximately 200° C. to 400° C., where 350° C. may be preferred.

Use of a hydrogen plasma inter-treatment may reduce S₁—CH₃ concentrations in the glue layer and may promote increased Si—O bonding at the interface between the glue layer and the interconnect structures and/or the IMD layer. The increased bonding induces greater stability in the IMD, as may be observed by Fourier transform infrared spectroscopy (FTIR), which characterizes materials based upon spectral adsorption bands. As previously described, the degree to which the inter-treatment improves the glue layer may depend upon the thickness of the glue layer. For example, applying the inter-treatment to a relatively thin glue layer may yield better electrical properties than the same inter-treatment applied to a relatively thick glue layer. Furthermore, the density of the glue layer may also determine the extent to which the inter-treatment improves the electrical properties of the glue layer.

Referring now to FIG. 4 and with continued reference to FIG. 1, after the inter-treatment is performed, a second metal layer 400 and additional layers (not shown) may be deposited onto the glue layer 300. The layer 400 may be a barrier layer formed from TiN, TaN, TiW, and/or other nitride containing refractory metals. The subsequent layers may include, for example, a copper layer or layers formed from other materials that may prevent copper diffusion, promote adhesion, or provide appropriate electrical properties. A copper layer formed using a damascene metallization process may be created by a single step electroplating process, a copper CVD seed followed by a bulk fill with electroplated copper, a copper PVD seed followed by a bulk fill with electroplated copper, a complete fill by PVD, or other methods known in the art.

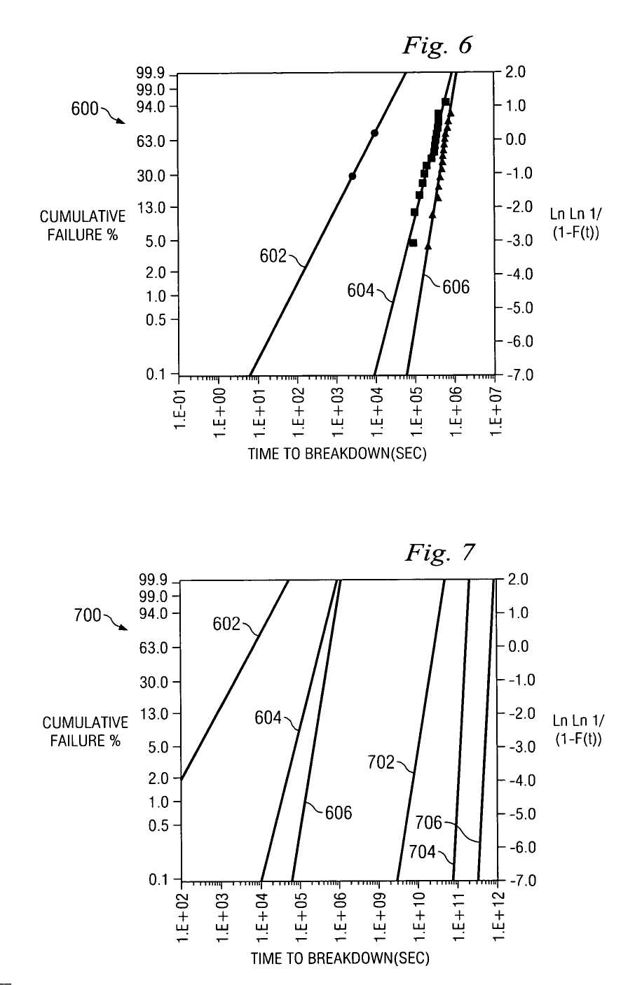

Referring now to FIG. 5, a graph 500 of line-to-line leakage current versus electrical stress field provides one example of the benefit provided by the previously described inter-treatment. Line 502 represents the line-to-line leakage current measured when an electrical stress is applied to a damascene structure created without the inter-treatment of step 108 of FIG. 1. Line 502 shows increasing line-to-line leakage current with an eventual catastrophic break down. Line 504 represents the line-to-line leakage current measured when an electrical stress is applied to a damascene structure created using the inter-treatment of step 108. In this example, the hydrogen based plasma used in the inter-treatment was created using H₂ as the reactant gas. As can be seen, line 504 illustrates a significantly reduced line-to-line leakage compared to line 502.

Referring now to FIGS. 6 and 7, a first graph 600 (FIG. 6) illustrates a Weibull distribution profile of TDDBs for IMDs that have not received the inter-treatment of step 108 of FIG. 1, and a second graph 700 (FIG. 7) illustrates a Weibull distribution profile of TDDBs for IMDs that have received the inter-treatment. Generally, a Weibull distribution profile illustrates the distribution of lifetimes of objects. In the present examples, the Weibull distribution profile is used to quantify TDDB lifetimes. In FIG. 6, the data sets 602, 604, 606 may be generated by changing the processing conditions used to create a damascene structure.

Referring specifically to FIG. 7, the data sets 702, 704, and 706 were generated using the processing conditions of data sets 602, 604, and 606, respectively, except that an inter-treatment was used when creating the damascene structures represented by the data sets 702, 704, and 706. As can be seen if FIG. 7, the data sets 702, 704, and 706 show a significant improvement in the TDDB lifetimes when compared with the data sets 602, 604, and 606.

The present invention has been described relative to a preferred embodiment. Improvements or modifications that become apparent to persons of ordinary skill in the art only after reading this disclosure are deemed within the spirit and scope of the application. The present invention may be applied and implemented on a variety of surfaces that may be of any shape—planar, curved, spherical, or three-dimensional. It is understood that several modifications, changes and substitutions are intended in the foregoing disclosure and in some instances some features of the invention will be employed without a corresponding use of other features. Accordingly, it is appropriate that the appended claims be construed broadly and in a manner consistent with the scope of the invention.

1. A method for increasing a time dependent dielectric breakdown lifetime of a semiconductor device having a first layer underlying a second layer, the method comprising:
forming a glue layer on the first layer;
performing an inter-treatment on the glue layer, wherein the inter-treatment improves an interface between the glue layer and the first layer; and
depositing the second layer onto the inter-treated glue layer.

2. The method of claim 1 further comprising performing a pre-treatment on the first layer before forming the glue layer.

3. The method of claim 1 wherein performing the inter-treatment on the glue layer includes applying a plasma to the glue layer.

4. The method of claim 3 wherein applying the plasma to the glue layer further includes selecting a reacting gas, a process time, a process temperature, a process pressure, and a reacting gas flow.

5. The method of claim 4 wherein the selected reacting gas is a hydrogen based gas.

6. The method of claim 4 wherein the selected reacting gas is a helium based gas.

7. The method of claim 4 wherein the selected process time is between approximately 1 and 100 seconds, the selected process temperature is between approximately 200 and 400° C., the selected process pressure is between approximately 0.5 and 10 torr, and the selected reacting gas flow is between approximately 100 and 2500 sccm.

8. The method of claim 1 wherein performing the inter-treatment on the glue layer includes directing an electron beam towards the glue layer.

9. The method of claim 8 wherein directing the electron beam towards the glue layer further comprises defining a process power and a dosage.

10. The method of claim 9 wherein the process power is between approximately 1000 eV and 8000 eV.

11. The method of claim 9 wherein the dosage is between approximately 50 and 500 μC/cm².

12. A method for increasing a dielectric breakdown lifetime of a semiconductor device, the method comprising:
depositing a dielectric layer;
depositing a glue layer on the dielectric layer;
selecting either a plasma treatment process or an electron beam treatment process; and
applying the selected treatment process to the glue layer, wherein the treatment process enhances an adhesiveness of the glue layer and the dielectric layer.

13. The method of claim 12 further comprising selecting a thickness for the glue layer, wherein the selected thickness is based at least partially on a desired electrical property of the glue layer.

14. The method of claim 13 further comprising adjusting a property of the selected treatment process based on the selected thickness of the glue layer.

15. The method of claim 14 wherein the adjusted property is associated with a duration of the selected treatment process.

16. The method of claim 12 further comprising selecting a glue for the glue layer, wherein the glue is selected from the group consisting of SiN, silicon oxide, SiCH, SiCN, and SiCO.

17. The method of claim 12 wherein the selected process is the plasma treatment process, and wherein a reacting gas to be used in the plasma treatment process is selected from the group consisting of a hydrogen based gas and a helium based gas.

18. A damascene structure having an increased time dependent dielectric breakdown lifetime, the structure comprising:
a first layer, wherein the first layer is at least partially formed from a dielectric material;
a treated glue layer adhering to the first layer, wherein the adhesiveness of the glue layer is due in part to a treatment performed on the glue layer prior to the deposition of any layer above the glue layer; and
a second layer formed on the glue layer.

19. The damascene structure of claim 18 wherein the glue layer includes an electrical property, and wherein the electrical property is determined by a density of the glue layer due to the density's effect on the treatment.

20. The damascene structure of claim 18 further comprising an adhesive layer underlying the first layer.
